(19) United States
(12) Patent Application Publication
(10) Pub. No.: US 2023/0192148 A1
(43) Pub. Date: Jun. 22, 2023

(54) METHOD AND SYSTEM FOR CLASSIFYING TRAFFIC SITUATIONS AND TRAINING METHOD

(71) Applicant: dSPACE GmbH, Paderborn (DE)

(72) Inventors: André ROSSI, Paderborn (DE); Luka KARAMAN, Zagreb (HR); Vjekoslav DIKLIC, Zagreb (HR); Cathrina SOWA, Paderborn (DE)

(73) Assignee: dSPACE GmbH, Paderborn (DE)

(21) Appl. No.: 18/084,633

(22) Filed: Dec. 20, 2022

(30) Foreign Application Priority Data
Dec. 21, 2021 (DE) 102021133979.0
Dec. 21, 2021 (EP) 21216241

(51) Int. Cl. B60W 60/00; G06F 18/24

(52) U.S. Cl. CPC B60W 60/00274; B60W 60/00272; G06F 18/24765; B60W 2520/125; B60W 2520/105

(57) ABSTRACT

A computer-implemented method and system for classifying traffic situations of a virtual test. The method comprises concatenating a plurality of determined data segments of the lateral and longitudinal behavior of the ego vehicle to identify vehicle actions and classifying traffic situations by linking a subset of the determined data segments of the lateral and longitudinal behavior of the ego vehicle with the identified vehicle actions. The invention further comprises a computer-implemented method for providing a trained machine learning algorithm for classifying traffic situations of a virtual test.

This nonprovisional application claims priority under 35 U.S.C. § 119(a) to German Patent Application No. 10 2021 133 979.0, and European Patent Application 21216241, which were both filed on Dec. 21, 2021, and which are herein incorporated by reference.

### BACKGROUND OF THE INVENTION

### Field of the Invention

The present invention relates to a computer-implemented method for classifying traffic situations of a virtual test. The present invention further relates to a computer-implemented method for providing a trained machine learning algorithm for classifying traffic situations of a virtual test. Moreover, the invention relates to a system for classifying traffic situations of a virtual test.

### Description of the Background Art

Test drives must be carried out to create test scenarios for simulations. The sensor data obtained in this way are then abstracted into a logical scenario.

Input data in this case are raw data, therefore, sensor data from real measurement runs in the sense of recordings of radar echoes, 3D point clouds from lidar measurements, and image data. Result data are simulatable driving scenarios, which comprise an environment on the one hand and trajectories on the other hand.

“Szenario-Optimierung für die Absicherung von automatisierten and autonomen Fahrsystemen” [Scenario Optimization for the Validation of Automated and Autonomous Driving Systems] discloses methods for verifying and validating automated and autonomous driving systems, in particular finding suitable test scenarios for virtual validation.

The test methodology foresees the adoption of a metaheuristic search to optimize scenarios. For this purpose, a suitable search space and a suitable fitness function needs to be created. Starting from an abstract description of the system's functionality and use cases, parameterized scenarios are derived.

It is assumed that certain parameters exert a great influence on the situation. For example, a situation in which emergency braking occurs is mainly determined by the speeds of the two road users. It is therefore of crucial importance for the user to be aware of a distribution of the values of these parameters and to know which parts are not covered by the data or the simulation. The missing data points must be collected either in reality or in the simulation.

An effective evaluation of the generated data set is therefore desirable for the user in order to identify critical situations and to test them in slightly varied versions of the same simulation scenario.

Consequently, there is a need to improve existing methods for analyzing driving scenario data sets to the effect that an effective identification and categorization of critical situations can be made possible.

### SUMMARY OF THE INVENTION

It is therefore an object of the present invention to provide a method for classifying traffic situations of a virtual test, which enables an effective identification and categorization of critical traffic situations.

The object is achieved according to the invention by a computer-implemented method for classifying traffic situations of a virtual test. The object is achieved further according to the invention by a computer-implemented method for providing a trained machine learning algorithm for classifying traffic situations of a virtual test. The object is achieved further according to the invention by a system for classifying traffic situations of a virtual test.

The invention relates to a computer-implemented method for classifying traffic situations of a virtual test.

The method comprises providing a first data set of sensor data of an ego vehicle run, captured by a first plurality of on-board environment detection sensors, and determining data segments, covered by the first data set, of the lateral and longitudinal behavior of the ego vehicle.

Further, the method comprises concatenating a plurality of the determined data segments of the lateral and longitudinal behavior of the ego vehicle to identify vehicle actions and classifying traffic situations by linking a subset of the determined data segments of the lateral and longitudinal behavior of the ego vehicle with the identified vehicle actions.

The method moreover comprises outputting a second data set having a plurality of classes, wherein a respective class of the plurality of classes represents a traffic situation of the virtual test.

The invention in addition relates to a computer-implemented method for providing a trained machine learning algorithm for classifying traffic situations of a virtual test.

The method comprises receiving a first training data set of sensor data of an ego vehicle run captured by a first plurality of on-board environment detection sensors, and receiving a second training data set having a plurality of classes, wherein a respective class of the plurality of classes represents a traffic situation of the virtual test.

Furthermore, the method comprises training the machine learning algorithm by an optimization algorithm that calculates an extreme value of a loss function for classifying traffic situations of the virtual test.

The invention in addition relates to a system for classifying traffic situations of a virtual test. The system comprises a first plurality of on-board environment detection sensors for providing a first data set of sensor data of an ego vehicle run.

Further, the system comprises a determinator for determining data segments, covered by the first data set, of the lateral and longitudinal behavior of the ego vehicle, and a concatenator for concatenating a plurality of the determined data segments of the lateral and longitudinal behavior of the ego vehicle to identify vehicle actions.

In general the term “ego vehicle” can represent a virtual vehicle in the center of a simulation or a test. E.g. the vehicle for that a new function is to be developed or tested. Typically, one skilled in the art uses such to distinguish a central vehicle (“ego”) from other vehicles or traffic participants (pedestrians, bicycles, etc.) that are usually called “fellows” or “fellow vehicles” that appear in a simulation or test and can interact or have an impact on the ego. For example, there may be several vehicles in a scenario in order to test a function of the ego vehicle but these fellow vehicles may not have the function to be tested, e.g. automatic braking systems.

The system further comprises a classifier for classifying traffic situations by linking a subset of the determined data segments of the lateral and longitudinal behavior of the ego vehicle with the identified vehicle actions, and an output for outputting a second data set having a plurality of classes, wherein a respective class of the plurality of classes represents a traffic situation of the virtual test.

An idea of the present invention is to perform an improved data selection and parameter extraction of traffic situations included in the data set of sensor data of an ego vehicle run captured by the first plurality of on-board environment detection sensors.

Thus, the data can be automatically searched for relevant situations using templates and then only the appropriately extracted traffic situations can be brought into the simulation.

Further, the templates extract parameter values of the relevant parameters. By collecting parameter values extracted from the same template for similar situations, a distribution can be created, and conclusions can be made about how these parameters need to be varied in order to cover unknown and possible critical situations in the simulation.

A traffic situation can be understood here as a small-scale, elementary, and/or larger-scale scenario or traffic scenario with a plurality of road users.

Templates include different algorithms that recognize different things at different levels of abstraction. In the context of the present invention, the algorithms are formed by the first, second, and third rule-based algorithms.

The first data set can comprise further sensor data of a run of at least one fellow vehicle and/or other road users, said run captured by a second plurality of on-board environment detection sensors. Thus, data from the other road users can advantageously also be used to classify the traffic situation.

Data segments, covered by the first data set, of the lateral and longitudinal behavior of the at least one fellow vehicle and/or other road users can be determined, wherein a plurality of the determined data segments of the lateral and longitudinal behavior of the at least one fellow vehicle and/or other road users are concatenated to identify vehicle actions, and wherein traffic situations are classified by linking a subset of the determined data segments of the lateral and longitudinal behavior of the at least one fellow vehicle and/or other road users with the identified vehicle actions.

Thus, vehicle actions can be classified in an advantageous manner from the respective individual data segments of the lateral and longitudinal behavior of the road users.

The classified traffic situations of the ego vehicle and the at least one fellow vehicle and/or other road users can be linked to form an interaction comprising the ego vehicle and the at least one fellow vehicle and/or other road users.

The models or traffic situations generated by the respective data of individual road users are thus advantageously linked to form an overall scenario comprising all data of all road users.

In identifying vehicle actions, the data segments of the lateral and longitudinal behavior of the ego vehicle can be combined into groups.

Combining into groups, especially in chronological order, thus advantageously makes it possible to abstract the individual data segments for a vehicle action, such as, for example, an overtaking maneuver or a lane change.

Determining data segments, covered by the first data set, of the lateral and longitudinal behavior of the ego vehicle can be carried out by applying a first rule-based algorithm, wherein concatenating the plurality of determined data segments of the lateral and longitudinal behavior of the ego vehicle to identify vehicle actions is carried out by applying a second rule-based algorithm, and wherein classifying traffic situations by linking the subset of the determined data segments of the lateral and longitudinal behavior of the ego vehicle with the identified vehicle actions is carried out by applying a third rule-based algorithm.

By using a plurality of rule-based algorithms, the multilayer model of the invention can efficiently build classifications of traffic situations.

The first rule-based algorithm, the second rule-based algorithm, and the third rule-based algorithm each can comprise different sets of rules for processing input data received by the respective algorithm. Each of the sets of rules is dedicated to one of the previously mentioned tasks, which are performed at a respective layer level.

Parameters of the classified traffic situations and/or interactions may be extracted for generating a parameter distribution of a predetermined parameter space. Thus, it can be determined in an advantageous manner which parameters are already covered in the given parameter space and which are still to be determined.

The data segments of the lateral and longitudinal behavior of the ego vehicle can comprise a constant or changing acceleration, position data, in particular GNSS data, and speed resulting therefrom. Vehicle actions can then be determined from these data segments in the subsequent layer.

The data segments of the lateral and longitudinal behavior of the ego vehicle can be formed by vectors, wherein respective vectors are added in concatenating the plurality of determined data segments of the lateral and longitudinal behavior of the ego vehicle to identify vehicle actions. The coding of the data segments by vectors has the advantage that they can be combined in an efficient manner in subsequent levels.

The sensor data of the ego vehicle run, captured by the first plurality of on-board environment detection sensors, can be position data of a GNSS sensor, IMU data, camera data, LiDAR data, and/or radar data, wherein the sensor data are annotated. Thus, sensor data from a plurality of different sensors can be used, which can increase the accuracy of a classification of traffic situations.

A third data set having a logical traffic scenario can be generated on the basis of the classified traffic situations and/or interactions. The extracted traffic situations and/or interactions that are interesting or critical for the user thus form the logical traffic scenario covered by the third data set.

The vehicle actions can comprise a change of direction and/or a lane change of the ego vehicle and/or of the at least one fellow vehicle and/or an interaction of the ego vehicle with a pedestrian, and the classified traffic situations comprise an overtaking action of the ego vehicle and/or of the at least one fellow vehicle. Thus, a variety of different vehicle actions can be advantageously extracted from the data.

The features described herein, of the computer-implemented method for classifying traffic situations of a virtual test are equally applicable to the system of the invention for classifying traffic situations of a virtual test and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a flowchart of a computer-implemented method for classifying traffic situations of a virtual test;

FIG. 2 shows a value distribution of extracted as well as non-extracted parameter values of the virtual test;

FIG. 3 shows a flowchart of a computer-implemented method for providing a trained machine learning algorithm for classifying traffic situations of a virtual test; and

FIG. 4 shows a schematic representation of a system for classifying traffic situations of a virtual test.

### DETAILED DESCRIPTION

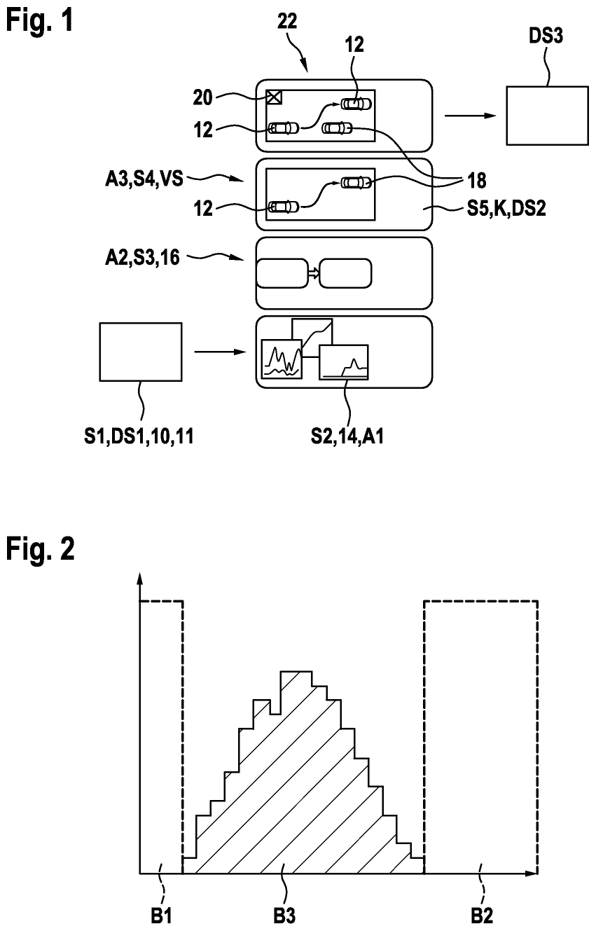

The method shown in FIG. 1 comprises providing S1 a first data set DS1 of sensor data of a run of an ego vehicle 12, said run captured by a first plurality of on-board environment detection sensors 10, and determining S2 data segments 14, covered by the first data set DS1, of the lateral and longitudinal behavior of ego vehicle 12.

The method further comprises concatenating S3 a plurality of determined data segments 14 of the lateral and longitudinal behavior of ego vehicle 12 to identify vehicle actions 16, and classifying S4 traffic situations VS by linking a subset of the determined data segments 14 of the lateral and longitudinal behavior of ego vehicle 12 with the identified vehicle actions 16.

In addition, the method comprises outputting S5 a second data set DS2 having a plurality of classes K, wherein a respective class K of the plurality of classes K represents a traffic situation VS of the virtual test.

The first data set DS1 further comprises additional sensor data of a run of the at least one fellow vehicle 18 and/or other road users 20, said run captured by a second plurality of on-board environment detection sensors 11. Data segments 14, covered by the first data set DS1, of the lateral and longitudinal behavior of the at least one fellow vehicle 18 and/or other road users 20 are then determined.

A plurality of the determined data segments 14 of the lateral and longitudinal behavior of the at least one fellow vehicle 18 and/or other road users 20 are concatenated to identify vehicle actions 16. Further, traffic situations VS are classified by linking a subset of the determined data segments 14 of the lateral and the longitudinal behavior of the at least one fellow vehicle 18 and/or other road users 20 with the identified vehicle actions 16.

The classified traffic situations VS of ego vehicle 12 and the at least one fellow vehicle 18 and/or other road users 20 are then linked to form an interaction 22 comprising ego vehicle 12 and the at least one fellow vehicle 18 and/or other road users 20.

In the process of identifying vehicle actions 16, data segments 14 of the lateral and longitudinal behavior of ego vehicle 12 are combined into groups.

Determining S2 data segments 14, covered by the first data set DS1, of the lateral and longitudinal behavior of ego vehicle 12 is carried out by applying a first rule-based algorithm A1.

Concatenating S3 the plurality of determined data segments 14 of the lateral and longitudinal behavior of ego vehicle 12 to identify vehicle actions 16 is carried out by applying a second rule-based algorithm A2. Classifying S4 traffic situations VS by linking the subset of determined data segments 14 of the lateral and longitudinal behavior of ego vehicle 12 with the identified vehicle actions 16 is further carried out by applying a third rule-based algorithm A3.

The first rule-based algorithm A1, the second rule-based algorithm A2, and the third rule-based algorithm A3 each comprise different sets of rules for processing input data received by the respective algorithm. Parameters of the classified traffic situations VS and/or interactions 22 are extracted for generating a parameter distribution of a given parameter space.

Data segments 14 of the lateral and longitudinal behavior of ego vehicle 12 comprise, for example, a constant or changing acceleration, position data, in particular GNSS data, and a speed resulting therefrom. Data segments 14 of the lateral and longitudinal behavior of ego vehicle 12 are further formed by vectors.

The respective vectors are added in concatenating S3 the plurality of determined data segments 14 of the lateral and longitudinal behavior of ego vehicle 12 to identify vehicle actions 16. The sensor data of the run, captured by the first plurality of on-board environment detection sensors 10, of ego vehicle 12 are position data of a GNSS sensor, IMU data, camera data, LiDAR data, and/or radar data, wherein the sensor data are annotated.

Based on the classified traffic situations VS and/or interactions 22, a third data set DS3 having a logical traffic scenario is generated.

Vehicle actions 16 comprise, for example, a direction change and/or a lane change of ego vehicle 12 and/or of the at least one fellow vehicle 18 and/or an interaction 22 of ego vehicle 12 with a pedestrian, and the classified traffic situations VS comprise an overtaking action of ego vehicle 12 and/or the at least one fellow vehicle 18.

Further, vehicle actions 16 can comprise one or more of the following traffic situations VS: a following behavior of vehicles, wherein a vehicle ahead brakes sharply, a close cutting-in of a vehicle in front of another vehicle, entering a major road with moving traffic, turning of a vehicle at an intersection, wherein the path intersects with that of another vehicle, a turning of a vehicle at an intersection in combination with an interaction 22 with a pedestrian crossing the road, driving along a road being crossed by a pedestrian, driving along a road on which a pedestrian is running in or against the direction of travel, driving along a road on which a bicyclist is riding in or against the direction of travel, and/or avoiding an obstacle placed on the road.

With reference to FIG. 1, the functionality of the computer-implemented method for classifying traffic situations VS of a virtual test is explained below using the example of a merging with subsequent tailgating.

Ego vehicle 12 stays in its lane and travels at a constant speed. Fellow vehicle 18 travels in the lane adjacent to ego vehicle 12; it then accelerates and changes lanes to the lane of ego vehicle 12.

The lowest layer shown in FIG. 1, which determines the data segments, covered by the first data set DS1, of the lateral and longitudinal behavior of ego vehicle 12 receives the complete raw data stream, including road information, trajectories, and speeds.

This layer abstracts the data stream for each vehicle 12, 14 into longitudinal data segments with constant acceleration from a speed distribution and lateral actions such as lane changes or lane keeping.

In the layer above this, in which a plurality of the determined data segments 14 of the lateral and longitudinal behavior of ego vehicle 12 are concatenated S3 to identify vehicle actions 16, a behavior is detected by clustering the lateral and longitudinal atoms. Then, an initial situation is classified by again merging the lateral and longitudinal behaviors.

For the ego vehicle, this means that lane keeping satisfies the conditions of the first two layers. For fellow vehicle 18, this means that there must be a lane change in the data.

The speed can be neglected for both vehicles during data selection, but it is needed for the parameterization of the simulation or the parameter extraction. Any vehicle that does not change lanes is therefore not an active vehicle.

The fourth layer, in which the classified traffic situations VS of ego vehicle 12 and the at least one fellow vehicle 18 and/or other road users 20 are linked into an interaction 22 comprising ego vehicle 12 and the at least one fellow vehicle 18 and/or other road users 20, combines the situations of both vehicles into one interaction.

The interaction layer ensures that fellow vehicle 18 performs the lane change ahead of ego vehicle 12 and that a time until a collision falls below a certain threshold.

If fellow vehicle 18, e.g., were to make the lane change far away from or even behind ego vehicle 12, this part of the data would be uninteresting. Thus, each vehicle and each data point that does not satisfy the conditions of all layers can be omitted, and thus in the end only the two vehicles exist that actively participate in the merging and only the images in which the merging takes place.

Each layer can include different algorithms which can be combined to detect different situations. With slightly changed conditions in one of the layers or by adding, e.g., a condition of another lane change, an overtaking maneuver could be detected instead. Other algorithms in different layers can be added, for example, to detect behavior at intersections.

After the situation layer, there is a set of logical blocks or units for each vehicle whose initial values are parameterized by the real data. Thus, e.g., the initial positions and speeds or the point at which the lane change begins are known. These are the parameters that are varied in a simulation-based test.

FIG. 2 shows a value distribution of extracted as well as non-extracted parameter values of the virtual test according to the preferred embodiment of the invention.

An option before the scenario-based testing would be to apply a template to many similar data streams and to extract the parameters. This would produce a distribution showing which parts of the value distribution are already covered (see region B3) and which are missing (see regions B1 and B2).

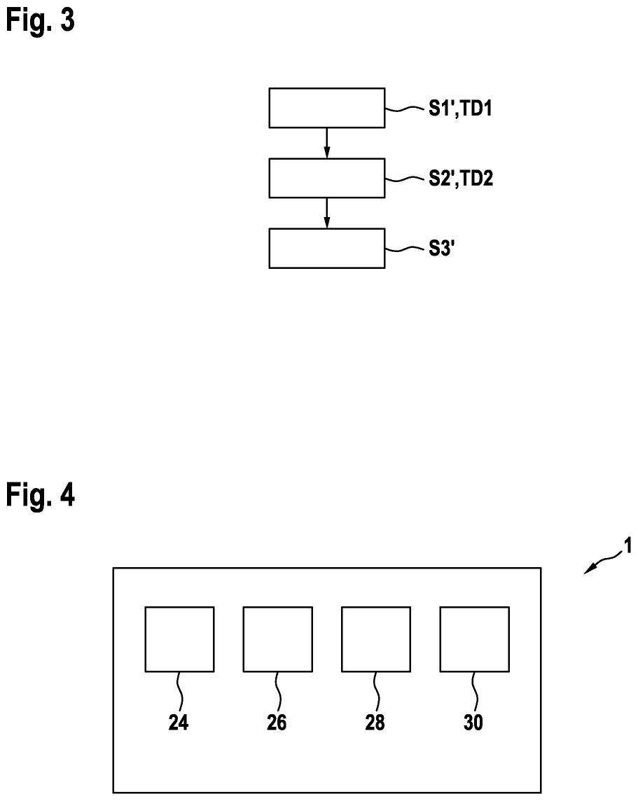

FIG. 3 shows a flowchart of a computer-implemented method for providing a trained machine learning algorithm for classifying traffic situations VS of a virtual test.

The method comprises receiving S1′ a first training data set TD1 of sensor data of a run, captured by a first plurality of on-board environment detection sensors 10, of an ego vehicle 12, and receiving S2′ a second training data set TD2 having a plurality of classes K, wherein a respective class K of the plurality of classes K represents a traffic situation VS of the virtual test.

Furthermore, the method comprises training S3′ the machine learning algorithm by an optimization algorithm that calculates an extreme value of a loss function for classifying traffic situations VS of the virtual test.

FIG. 4 shows a schematic representation of a system for classifying traffic situations VS of a virtual test according to the preferred embodiment of the invention.

The system comprises a first plurality of on-board environment detection sensors 10 for providing a first data set DS1 of sensor data of a run of an ego vehicle 12, and a determinator 24 for determining data segments 14, covered by the first data set DS1, of the lateral and longitudinal behavior of ego vehicle 12.

Further, the system comprises a concatenator 26 for concatenating a plurality of the determined data segments 14 of the lateral and longitudinal behavior of ego vehicle 12 to identify vehicle actions 16, and a classifier 28 for classifying traffic situations VS by linking a subset of the determined data segments 14 of the lateral and longitudinal behavior of ego vehicle 12 with the identified vehicle actions 16.

The system further comprises an output 30 for outputting a second data set DS2 having a plurality of classes K, wherein a respective class K of the plurality of classes K represents a traffic situation VS of the virtual test.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method for classifying traffic situations of a virtual test, the method comprising:
providing a first data set of sensor data of a run, captured by a first plurality of on-board environment detection sensors of an ego vehicle;
determining data segments covered by the first data set of a lateral and longitudinal behavior of the ego vehicle;
concatenating a plurality of determined data segments of the lateral and longitudinal behavior of the ego vehicle to identify vehicle actions;
classifying traffic situations by linking a subset of the determined data segments of the lateral and longitudinal behavior of the ego vehicle with the identified vehicle actions; and
outputting a second data set having a plurality of classes,
wherein a respective class of the plurality of classes represents a traffic situation of the virtual test.

2. The computer-implemented method according to claim 1, wherein the first data set comprises further sensor data of a run of at least one fellow vehicle and/or other road users, said run being captured by a second plurality of on-board environment detection sensors.

3. The computer-implemented method according to claim 2, wherein data segments covered by the first data set of the lateral and longitudinal behavior of the at least one fellow vehicle and/or other road users are determined, wherein a plurality of the determined data segments of the lateral and longitudinal behavior of the at least one fellow vehicle and/or other road users are concatenated to identify vehicle actions, and wherein traffic situations are classified by linking a subset of the determined data segments of the lateral and longitudinal behavior of the at least one fellow vehicle and/or other road users with the identified vehicle actions.

4. The computer-implemented method according to claim 3, wherein the classified traffic situations of the ego vehicle and of the at least one fellow vehicle and/or of other road users are linked to form an interaction comprising the ego vehicle and the at least one fellow vehicle and/or other road users.

5. The computer-implemented method according to claim 1, wherein in identifying vehicle actions, the data segments of the lateral and longitudinal behavior of the ego vehicle are combined into groups.

6. The computer-implemented method according to claim 1, wherein determining data segments covered by the first data set of the lateral and longitudinal behavior of the ego vehicle is carried out by applying a first rule-based algorithm, wherein concatenating the plurality of determined data segments of the lateral and longitudinal behavior of the ego vehicle to identify vehicle actions is carried out by applying a second rule-based algorithm, and wherein classifying traffic situations by linking the subset of determined data segments of the lateral and longitudinal behavior of the ego vehicle with the identified vehicle actions is carried out by applying a third rule-based algorithm.

7. The computer-implemented method according to claim 6, wherein the first rule-based algorithm, the second rule-based algorithm, and the third rule-based algorithm each comprise different sets of rules for processing input data received by the respective algorithm.

8. The computer-implemented method according to claim 4, wherein parameters of the classified traffic situations and/or interactions are extracted for generating a parameter distribution of a predetermined parameter space.

9. The computer-implemented method according to claim 1, wherein the data segments of the lateral and longitudinal behavior of the ego vehicle comprise a constant or changing acceleration, position data, GNSS data, and/or speed resulting therefrom.

10. The computer-implemented method according to claim 1, wherein the data segments of the lateral and longitudinal behavior of the ego vehicle are formed by vectors, wherein respective vectors are added in concatenating the plurality of determined data segments of the lateral and longitudinal behavior of the ego vehicle to identify vehicle actions.

11. The computer-implemented method according to claim 1, wherein the sensor data of the run, captured by the first plurality of on-board environment detection sensors of the ego vehicle are position data of a GNSS sensor, IMU data, camera data, LiDAR data, and/or radar data, and wherein the sensor data are annotated.

12. The computer-implemented method according to claim 4, wherein a third data set having a logical traffic scenario is generated on the basis of the classified traffic situations and/or interactions.

13. The computer-implemented method according to claim 1, wherein the vehicle actions comprise a change of direction and/or a lane change of the ego vehicle and/or of the at least one fellow vehicle and/or an interaction of the ego vehicle with a pedestrian, and wherein the classified traffic situations comprises an overtaking process of the ego vehicle and/or of the at least one fellow vehicle.

14. A computer-implemented method for providing a trained machine learning algorithm for classifying traffic situations of a virtual test, the method comprising:
receiving a first training data set of sensor data of a run, captured by a first plurality of on-board environment detection sensors of an ego vehicle;
receiving a second training data set having a plurality of classes, wherein a respective class of the plurality of classes represents a traffic situation of the virtual test; and
training the machine learning algorithm by an optimization algorithm that calculates an extreme value of a loss function for classifying traffic situations of the virtual test.

15. A system for classifying traffic situations of a virtual test, the system comprising:
a first plurality of on-board environment detection sensors to provide a first data set of sensor data of a run of an ego vehicle;
a determinator tor determine data segments covered by the first data set of the lateral and longitudinal behavior of the ego vehicle;
a concatenator to concatenate a plurality of the determined data segments of the lateral and longitudinal behavior of the ego vehicle to identify vehicle actions;
a classifier to classify traffic situations by linking a subset of the determined data segments of the lateral and longitudinal behavior of the ego vehicle with the identified vehicle actions; and
an output to output a second data set having a plurality of classes, wherein a respective class of the plurality of classes represents a traffic situation of the virtual test.
